(19) United States
(12) Patent Application Publication
(10) Pub. No.: US 2003/0111720 A1
(43) Pub. Date: Jun. 19, 2003

(54) Stacked die semiconductor device

(76) Inventors: Lan Chu Tan, Klang (MY); Cheng Choi Yong, Puchong (MY); Chee Seng Foong, Sg. Buloh (MY); Ruzaini Bin Ibrahim, Shah Alam (MY)

Correspondence Address: MOTOROLA, INC., CORPORATE LAW DEPARTMENT - #56-238, 3102 NORTH 56TH STREET, PHOENIX, AZ, 85018, US

(21) Appl. No.: 10/023,128

(22) Filed: Dec. 18, 2001

(51) Int. Cl. H01L 29/93

(52) U.S. Cl. 257/686

(57) ABSTRACT

An integrated circuit die (106) of a stacked multichip package (100) has a body (122) with a bottom surface (124) for being adhered to a surface of another integrated circuit die (104) of the stacked multichip package (100), and a top surface (126). The top surface (126) includes bonding pads (128). The body (122) also includes steps (130) extending along a periphery of the bottom surface (124) such that an area of the bottom surface (124) is less than an area of the top surface (126) and such that the die (106) has a T-shaped cross-section. When the die (106) is attached on top of another die (104), the steps (130) form a space for the wirebonds of the wires connecting the other die (104) to a carrier (102).

### BACKGROUND OF THE INVENTION

The present invention relates to integrated circuits and a method of packaging integrated circuits and, more particularly, to stacked multi-chip package type integrated circuits.

An integrated circuit (IC) die is a small device formed on a semiconductor wafer, such as a silicon wafer. Such a die is typically cut from the wafer and attached to a base carrier for interconnect redistribution. Bond pads on the die are then electrically connected to the leads on the carrier via wire bonding. The die and wire bonds are encapsulated with a protective material such that a package is formed. The leads encapsulated in the package are redistributed in a network of conductors within the carrier and end in an array of terminal points outside the package. Depending on the package types, these terminal points may be used as-is, such as in TSOP, or further processed, such as attaching spherical solder balls for a Ball Grid Array (BGA). The terminal points allow the die to be electrically connected with other circuits, such as on a printed circuit board. In subsequent examples, a MAPBGA is used to illustrate the invention disclosed herein.

With the goal of increasing the amount of circuitry in a package, but without increasing the area of the package so that the package does not take up any more space on the circuit board, manufacturers have been stacking two or more die within a single package. Such devices are sometimes referred to as stacked multichip packages. FIG. 1 shows a first conventional stacked multichip package 10. The package 10 includes a first or bottom die 12 attached to a base carrier 14 (in this example, a MAPBGA substrate) with a first adhesive layer 16. A second or top die 18 is attached to the bottom die 12 with a second adhesive layer 20 similar to the first adhesive layer 16. The bottom and top dice 12, 18 are electrically connected to the base carrier 14 with wires 22 and 24, respectively, via wirebonding. Terminals 26, in this case spherical solder ball terminals, are connected to a network or redistribution layer (not shown) of the base carrier 14. The bottom and top dice 12, 18 and the wires 22, 24 are sealed with a resin 28, thus forming the stacked multichip package 10. In order to allow the bottom die 12 to be wirebonded to the leads of the base carrier 14, the top die 18 must be smaller than the bottom die 12.

FIG. 2 shows a second conventional stacked multichip package 30. The second package 30 includes a first or bottom die 32 attached to a base carrier or substrate 34 with a first adhesive layer 36. Bond pads on the bottom die 32 are electrically connected to leads on the substrate 34 with first wires 38 via wirebonding. A spacer 40, typically made of bare silicon, is attached to the bottom die 32 with a second adhesive layer 42. A third or top die 44 is attached to the spacer 40 with a third adhesive layer 46.

The top die 44 is almost the same size or bigger than the bottom die 32. In such a situation, wirebonding of the bottom die 32 is impossible if the top and bottom dice 32, 44 are attached as shown in FIG. 1 (i.e., without the spacer 40). However, as shown in the drawing, the spacer 40 is smaller than the bottom die 32 so that the bottom die 32 may be wirebonded without obstruction. Thus, bond pads on the top die 44 are electrically connected to the substrate 24 with second wires 48 via wirebonding.

The total thickness of the spacer 40 and the second and third adhesive layers 42 and 46 must also be large enough so that the wires 38 connected to the bottom die 32 are not disturbed when the top die 44 is attached to the spacer 40. Spherical solder ball terminals 50 are connected to a wiring layer (not shown) of the substrate 34. The bottom die 32, top die 44, spacer 40 and the wires 38, 48 are sealed with a resin 52, thus forming the stacked multichip package 30. While this solution allows two die with almost the same size to be packaged together, the spacer 40 increases the process lead time, cost and size (height) of the package 30.

It would be desirable to be able to stack two or more die of the same size, or an even larger top die in a single package without unduly increasing the size of the resulting package and without the requirement of a spacer.

### BRIEF DESCRIPTION OF THE DRAWINGS

The foregoing summary, as well as the following detailed description of preferred embodiments of the invention, will be better understood when read in conjunction with the appended drawings. For the purpose of illustrating the invention, there is shown in the drawings embodiments that are presently preferred. It should be understood, however, that the invention is not limited to the precise arrangements and instrumentalities shown. In the drawings:

FIG. 1 is an enlarged side view of a first conventional stacked multichip package;

FIG. 2 is an enlarged side view of a second conventional stacked multichip package;

FIG. 3 is an enlarged side view of a stacked multichip package in accordance with a first embodiment of the invention;

FIG. 4 is an enlarged side view of a top die of the multichip package of FIG. 3; and

FIG. 5 is a flowchart illustrating the steps for forming the stacked multichip package of FIG. 3.

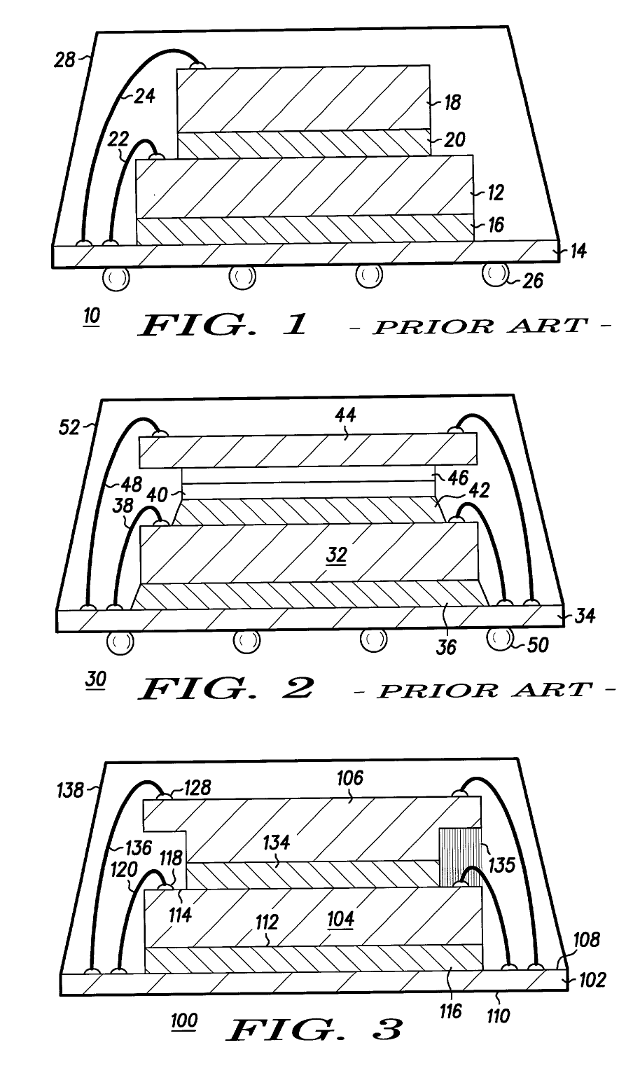

### DETAILED DESCRIPTION OF PREFERRED EMBODIMENTS

The detailed description set forth below in connection with the appended drawings is intended as a description of the presently preferred embodiments of the invention, and is not intended to represent the only forms in which the present invention may be practiced. It is to be understood that the same or equivalent functions may be accomplished by different embodiments that are intended to be encompassed within the spirit and scope of the invention. For simplicity, examples used to illustrate the invention refer only to a package having two stacked dice. However, the same invention in fact can be applied to packages having more than two stacked dice.

Certain features in the drawings have been enlarged for ease of illustration and the drawings and the elements thereof are not necessarily in proper proportion. However, those of ordinary skill in the art will readily understand such details. In the drawings, like numerals are used to indicate like elements throughout.

In order to provide a stacked multichip package in which a top die is about the same size or larger than a bottom die, the present invention is a top die including a body having a bottom surface for being adhered to the top surface of a bottom die of the multichip package. The top surface of the top die includes a plurality of bonding pads. The body of the top die includes steps extending along opposing sides of the bottom surface such that an area of the bottom surface is less than the area of the top surface of the top die.

The present invention also provides a multichip package including a substrate with a top surface and a bottom surface, and a bottom die having a top surface and a bottom surface. The bottom surface of the bottom die is attached to the top surface of the substrate. A second, top die has a body with a bottom surface for being adhered to the top surface of the first die, and a top surface that includes a plurality of bonding pads. The body of the top die includes steps extending along opposing sides of the bottom surface such that an area of the bottom surface is less than an area of the top surface. The steps provide adequate spacing between the top and bottom dice to allow bonding pads on the top surface of the bottom die to be wirebonded to corresponding pads on the substrate.

The present invention also provides a method of making a stacked multichip package including the steps of:

attaching a first integrated circuit die to a substrate or base carrier, the first die having a top surface and a bottom surface, wherein the bottom surface is attached to the substrate and wherein the top surface has a central area and a peripheral area, the peripheral area including a plurality of bonding pads;

electrically connecting the first die to first leads on the substrate by wirebonding first wires to the bonding pads of the first die and corresponding first leads on the substrate;

forming steps in a bottom surface of a second integrated circuit die, the steps being formed along a peripheral edge of the bottom surface such that the second die has a T-shaped cross-section;

attaching the bottom surface of the second die to the central area of the first die top surface; and

electrically connecting the second die to the substrate by wirebonding second wires to bonding pads located on a top surface of the second die to corresponding second leads on the substrate.

The present invention also provides a method of preparing an integrated circuit die for a stacked multichip package, including the formation of steps in a bottom surface of the integrated circuit die. The steps are formed along a peripheral edge of the bottom surface so that the die has a T-shaped cross-section.

Referring now to FIG. 3, an enlarged side view of a stacked multichip package 100 in accordance with the present invention is shown. The stacked multichip package 100 includes a base carrier or substrate 102, a bottom die 104 and a top die 106. The substrate 102 and the bottom die 104 are well known to those of ordinary skill in the art. The top die 106 is also of a type well known to those of ordinary skill in the art except for the changes to the physical shape of the top die 106 described in detail below.

The bottom die 104 and the top die 106 preferably have substantially the same length and width dimensions. However, the top die 106 may be somewhat larger or somewhat smaller than the bottom die 104. For example, typical bottom and top die sizes may range from 4 mm×4 mm to 12 mm×12 mm. The bottom and top dice 104, 106 may also have the same thickness, however, this is not required. Depending on the required final package outline thickness, the bottom and top die may have a thickness ranging from about 6 mils to about 21 mils.

The substrate 102 has a top surface 108 and a bottom surface 110. The bottom die 104 has a bottom surface 112 and a second, opposing top surface 114. The bottom surface 112 of the bottom die 104 is attached to the top surface 108 of the substrate 102. Preferably, the bottom die 104 is attached to the substrate 102 with a first adhesive material layer 116. The first adhesive material layer 116 may be any suitable adhesive material, such as an adhesive tape, a thermoplastic adhesive, an epoxy material, or the like. Adhesives suitable for attaching an integrated circuit die to a substrate are well known to those of skill in the art.

The bottom die 104 has a plurality of bonding pads 118 located around the periphery of the top surface 114. The bottom die 104 is electrically connected to leads (not shown) on the substrate 102 with first wires 120. More particularly, one end of the first wires 120 is electrically connected to bonding pads 118 on the top surface 114 of the bottom die 104, and opposing ends of the first wires 120 are wirebonded to the leads located on the top surface 108 of the substrate 102.

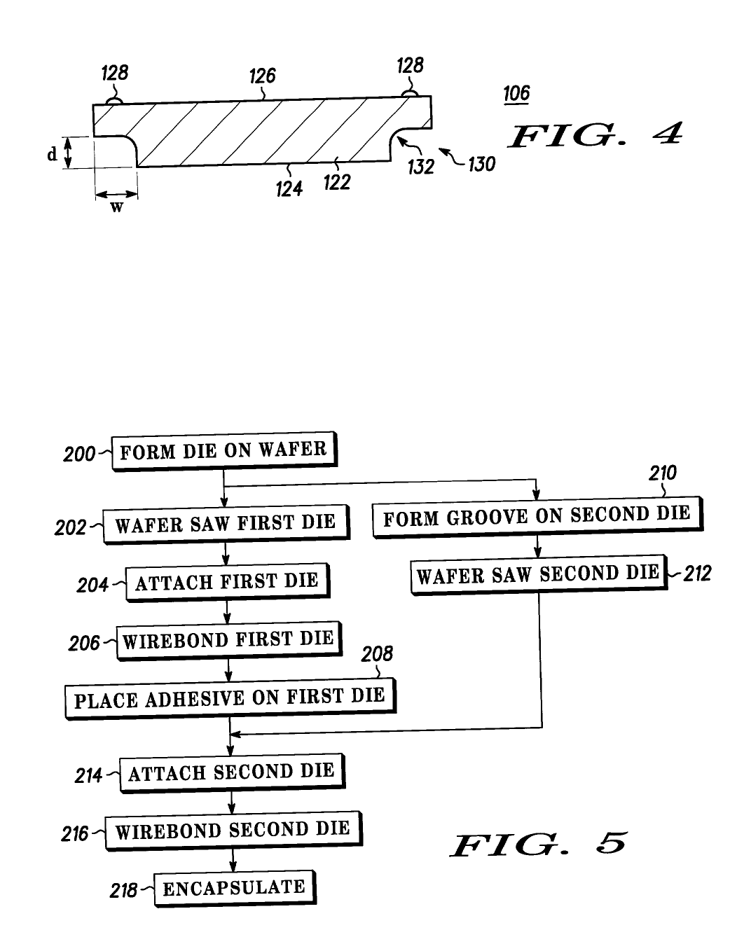

Referring now to FIG. 3 and FIG. 4, the top die 106 has a central body 122 with a bottom surface 124 for being adhered to the top surface 114 of the bottom die 104. The top die 106 also has a top surface 126 opposing the bottom surface 124. The top surface 126 includes a plurality of bonding pads 128. Preferably, the bonding pads 128 are located around the periphery of the top surface 126. In the drawings, the bonding pads 118 and 128 are shown as protruding from the surfaces of the dice 104 and 106, respectively, for illustration purposes.

The body 122 of the top die 106 includes steps 130 that extend along opposing sides of the bottom surface 124 such that an area of the bottom surface 124 is less than an area of the top surface 126. The steps 130 give the top die 106 a generally T-shaped cross-section. The steps 130 are sized to allow for adequate spacing between the top die 106 and the first wires 120 when the top die 106 is attached to the bottom die 104, as shown in FIG. 3 and discussed below. For example, the steps 130 may have a depth ‘d’ of about 80 microns and a width ‘w’ of about 0.3 mm. The steps 130 may also have rounded edges 132 depending on the method used to produce the steps.

The top die 106 is attached to the bottom die 104 with a second adhesive material layer 134. More specifically, the bottom surface 124 of the top die 106 is attached to a central area of the top surface 114 of the bottom die 104. The second adhesive material layer 134 may be comprised of the same type of materials as the first adhesive material layer 116 used to attach the bottom die 104 to the substrate 102. When the top die 106 is attached to the bottom die 104, a portion of the first wires 120 adjacent to the first ends thereof is located within the steps 130 of the top die 106. As previously discussed, the steps 130 are sized and shaped so that the wirebonds of the first wires 120 are not damaged or compromised when the top die 106 is attached to the bottom die 104.

In one embodiment of the invention, extra non-conductive epoxy or adhesive material 135 may be used to fill the steps 130, thereby further protecting the wirebonds therein.

The top die 106 is electrically connected to leads on the top surface 108 of the substrate 102 with second wires 136. The second wires 136 have first ends electrically connected to the bonding pads 128 on the top die 106 and second ends wirebonded to the leads located on the top surface 108 of the substrate 102.

An encapsulant material 138, such as resin, may be used to cover the top and bottom integrated circuit dice 104, 106 and the first and second bond wires 120, 136.

Referring now to FIG. 5, a method of making a stacked multichip package in accordance with the present invention is shown. Integrated circuit dice are fabricated on wafers in a first step 200 in a manner known by those of skill in the art. A die to be used in the stacked multichip package, such as the bottom die 104 is then sawn from the wafer in a second step 202. In a third step 204, the bottom die 104 is attached to a base carrier or substrate, such as the substrate 102. As previously discussed, the bottom die 104 can be attached to the substrate 102 in a known manner, such as with an adhesive tape or an epoxy. More particularly, a first or bottom surface of the first die 104 is attached to a top surface of the substrate 102.

After the bottom die 104 is attached to the substrate 102, the bottom die 104 is electrically connected to the substrate 102 via wirebonding, in a fourth step 206. The top surface of the bottom die 104 has a plurality of bonding pads spaced along its periphery. First bonding wires are wirebonded to this plurality of bonding pads and to a corresponding plurality of leads on the substrate 102.

In step 208, an adhesive or adhesive material is placed on a central area of the top surface of the bottom die 104 so that a top die, such as the top die 106 can be attached to the bottom die 104, in step 214.

The top die 106 (after being cut from the wafer upon which it is grown) preferably has generally the same or larger dimensions as the bottom die 104. That is, the bottom and top dice 104, 106 have substantially the same length and width or the top die 106 may have a larger length and/or width than the bottom die 104. For example, typical bottom and top die sizes may range from 4 mm×4 mm to 12 mm×12 mm. The bottom and top dice 104, 106 may also have the same thickness, however, this is not required. Depending on the required final package outline thickness, the bottom and top die may have a thickness ranging from about 6 mils to about 21 mils.

Prior to attaching the top die 106 to the bottom die 104, steps like the steps 130 are formed in the top die 106. Thus, in step 210, steps are formed in the bottom surface of the top die 106. The steps are formed along the peripheral edge of the bottom surface so that the top die 106 has a T-shaped cross-section. The steps are sized and shaped to accommodate the wirebonds of the first wires 120 where the first wires 120 are connected to the bottom die 104. For example, for a die size of 4.5 mm×4.5 mm×11 mils, the steps may have a depth of about 100 microns and a width of about 0.3 mm.

The steps can be formed in the top die 106 by a number of methods. A first method comprises chemical etching of trenches at the bottom surface 124 of the top die 106 directly below the saw streets. Photo-resist masks are coated outside the trenches. Areas not coated, in this case the trenches will be etched away to form the steps. Chemical etching is well known to those of ordinary skill in the art. A normal wafer saw (with blade width narrower than the trench width) following the trench etching will produce the T-shaped die having the aforedescribed steps. A second method comprises dry etching of the trenches using plasma. Masking similar to that described in the first method is used to cover the bottom surface 124 of the top die 106 so that the plasma will remove only the trench area. Alternatively, a metal-based masking such as an Aluminum mask may also be used. Plasma etching is also well known to those of ordinary skill in the art. Again, a normal wafer saw saw (with blade width narrower than the trench width) following the trench etching will produce the T-shaped die with the required steps. A third method of forming steps involves sawing the bottom surface of the die using a conventional wafer saw machine. The saw blade is controlled to remove only a predefined material depth and width along the bottom surface 124 of the top die 106, directly below the saw streets on the top surface 126 of the top die 106. This process will produce steps in the bottom surface 124 of the top die 106 without severing the wafer or separating the die. A normal wafer saw using a narrower blade following the controlled sawing operation is performed to separate the die, thus yielding the T-shaped dice with the required steps. In each of the three methods described above, it is preferred to have round edges at the corners of the steps, as shown at 132 (FIG. 4). The rounded edges 132 reduce stress at the side ends of the top die 106, especially if the steps are filled with epoxy or another material after the bottom die 104 is wirebonded to the substrate 102.

In step 212, the top die 106 is sawn from the wafer upon which it was formed. Although the drawing shows step 210 being performed before step 212, step 210 can be performed any time prior to attaching the top die 106 to the bottom die 104. That is, step 210 can be performed after the top die 106 has been sawn from its wafer. Note also that steps 210 and 212 can be performed in parallel with steps 202 to 208.

In step 214, the top die 106 is attached to the bottom die 104. Specifically, a bottom surface of the top die 106 is attached to a central area of the top surface 114 of the bottom die 104. The top die 106 can then be electrically connected to the substrate 102 via wirebonding. The second wires 136 are wirebonded to the bonding pads 128 of the top die 106 and corresponding leads (not shown) on the substrate 102.

Finally, in step 218, the bottom and top dice 104, 106 and the first and second wires 120, 136 are covered with an encapsulant. The resulting stacked multichip package has two, almost same-sized stacked die, yet the overall package height is less than the package height of the prior art stacked die package that includes a dummy, spacer die. The cost of the stacked multichip package is also reduced because a dummy die is not required and the step of attaching the dummy die is not required.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. For example, the present invention is not limited to any single wire bonding technique or to a particular package. That is, the invention is applicable to all wire bonded package types, including but not limited to BGA, QFN, QFP, PLCC, CUEBGA, TBGA, and TSOP. In addition, the die sizes and the dimensions of the steps may vary to accommodate the required package design. It is understood, therefore, that this invention is not limited to the particular embodiments disclosed, but covers modifications within the spirit and scope of the present invention as defined by the appended claims.

1. An integrated circuit die of a stacked multichip package, the integrated circuit die comprising:
a body having a bottom surface for being adhered to a surface of another integrated circuit die of the stacked multichip package, and a top surface, the top surface including a plurality of bonding pads, wherein the body includes steps extending along opposing sides of the bottom surface such that an area of the bottom surface is less than an area of the top surface.

2. The integrated circuit die of claim 1, wherein the die is generally T-shaped in cross-section.

3. The integrated circuit die of claim 1, wherein the top surface includes a central area and peripheral area and the bonding pads are located in the peripheral area.

4. The integrated circuit die of claim 1, wherein the steps are formed by one of chemical etching, plasma etching, and mechanical sawing.

5. The integrated circuit die of claim 1, wherein the steps have a predetermined depth suitable for accommodating a wire bond of a bond wire wirebonded to the surface of the other die to which the integrated circuit die is adhered.

6. The integrated circuit die of claim 1, wherein the grooves have a predetermined width suitable for the accommodating a wire bond of a bond wire wirebonded to the surface of the other die to which the integrated circuit die is adhered.

7. The integrated circuit die of claim 1, wherein corners of the steps are rounded.

8. A stacked multichip package, comprising:
a base carrier having a top side and a bottom side;
a bottom integrated circuit die having a top surface and a bottom, opposing surface, wherein the bottom surface of the first integrated circuit die is attached to the top side of the base carrier; and
a top integrated circuit die, the top integrated circuit die having a body with a bottom surface attached to the top surface of the bottom integrated circuit die, and a top surface, the top die top surface including a plurality of bonding pads, wherein the body includes steps extending along opposing sides of the bottom surface such that an area of the bottom surface is less than an area of the top surface.

9. The stacked multichip package of claim 8, wherein the bottom integrated circuit die is attached to the base carrier with a first adhesive material layer.

10. The stacked multichip package of claim 9, wherein the top integrated circuit die is attached to the bottom integrated circuit die with a second adhesive material layer.

11. The stacked multichip package of claim 8, wherein the top integrated circuit die and the bottom integrated circuit die are generally the same in length and width.

12. The stacked multichip package of claim 8, wherein the top integrated circuit die is larger than the bottom integrated circuit die in length and width.

13. The stacked multichip package of claim 8, wherein the bottom integrated circuit die is electrically connected to the base carrier with first wires, the first wires having first ends electrically connected to a plurality of bonding pads located on an exposed area of the top surface of the bottom integrated circuit die and second ends wirebonded to first leads on the top side of the base carrier.

14. The stacked multichip package of claim 13, wherein a portion of the first wires adjacent to the first ends thereof is located within the steps area of the top integrated circuit die.

15. The stacked multichip package of claim 14, wherein the top integrated circuit die is electrically connected to the top side of the base carrier with second wires, the second wire having first ends electrically connected to the plurality of bonding pads located on the top surface of the top integrated circuit die and second ends electrically connected to second leads on the top side of the base carrier.

16. The stacked multichip package of claim 14, further comprising an encapsulant covering the first and second integrated circuit dice and the first and second wires.

17. A method of making a stacked multichip package comprising the steps of:
attaching a bottom integrated circuit die to a base carrier, the bottom die having a top surface and a bottom surface, wherein the bottom surface is attached to the base carrier and wherein the top surface has a central area and a peripheral area, the peripheral area including a plurality of first bonding pads;
electrically connecting the bottom die to the base carrier by wirebonding first wires to the plurality of first bonding pads of the bottom die and to corresponding first leads on the base carrier;
forming steps in a bottom surface of a top integrated circuit die, the steps being formed along a peripheral edge of the bottom surface so that the top die has a T-shaped cross-section;
attaching the bottom surface of the top die to the central area of the bottom die top surface; and
electrically connecting the top die to the base carrier by wirebonding second wires to second bonding pads located on a top surface of the top die and to corresponding second leads on the base carrier.

18. The method of making a stacked multichip package of claim 17, wherein the bottom and top dice have substantially the same length and substantially the same width.

19. The method of making a stacked multichip package of claim 17, wherein the top die has a larger length and width than the bottom die.

20. The method of making a stacked multichip package of claim 17, wherein the steps formed in the top die form a space for accommodating the wirebonds of the first wires to the first plurality of bonding pads.

21. The method of making a stacked multichip package of claim 17, wherein the steps formed in the top die are formed by one of chemical etching, plasma etching, and mechanical sawing.

22. The method of making a stacked multichip package of claim 21, wherein the steps are formed in the top die before the die is picked from the wafer upon which the die was formed.

23. The method of making a stacked multichip package of claim 17, wherein corners of the steps are rounded.

24. The method of making a stacked multichip package of claim 17, further comprising the step of sealing the top and bottom die and the first and second wires with a resin.

25. A method of preparing an integrated circuit die for a stacked multichip package, the method comprising the steps of:
forming steps in a bottom surface of the integrated circuit die, the steps being formed along a peripheral edge of the bottom surface so that the die has a T-shaped cross-section.

26. The method of preparing an integrated circuit die of claim 25, wherein the steps have a predetermined depth suitable for accommodating a wire bond of a bond wire wirebonded to a surface of another die to which the integrated circuit die is adhered.

27. The method of preparing an integrated circuit die of claim 25, wherein the groove has a predetermined width suitable for accommodating a wire bond of a bond wire wirebonded to a surface of another die to which the integrated circuit die is adhered.

28. The method of preparing an integrated circuit die of claim 25, further comprising the step of rounding the corners of the steps.

29. The method of preparing an integrated circuit die of claim 25, wherein the steps are formed in the die before the die is picked from the wafer upon which the die was formed.

30. The method of preparing an integrated circuit die of claim 25, wherein the steps are formed by one of chemical etching, plasma etching, and mechanical sawing.
